(19) United States
(12) Patent Application Publication
(10) Pub. No.: US 2025/0349735 A1
(43) Pub. Date: Nov. 13, 2025

(54) SEMICONDUCTOR DEVICE AND METHOD FOR MANUFACTURING THE SAME

(71) Applicant: Samsung Electronics Co., Ltd., Suwon-si (KR)

(72) Inventors: Woohyuk Jang, Suwon-si (KR); Yanghee Lee, Suwon-si (KR); Sujeong Kim, Suwon-si (KR); Jin-Woo Bae, Suwon-si (KR); Jin Soon Han, Suwon-si (KR); Hyunsu Hwang, Suwon-si (KR)

(21) Appl. No.: 18/967,937

(22) Filed: Dec. 4, 2024

(30) Foreign Application Priority Data
May 8, 2024 (KR) 10-2024-0060374

(51) Int. Cl. H01L 23/544; H01L 23/528; H01L 23/532

(52) U.S. Cl. CPC H01L 23/544; H01L 23/5283; H01L 23/53271; H01L 2223/54426

(57) ABSTRACT

A semiconductor device includes a substrate that includes a first area and a second area, a first active pattern in the first area, a bit-line structure on the first area, a buried contact that is on a side surface of the bit-line structure and is electrically connected to the first active pattern of the first area, an alignment key structure that is on the second area and defines a key trench, and a buried pattern in at least a portion of the key trench, where the buried contact and the buried pattern include a first conductive material, and where, relative to an upper surface of the substrate and in a direction that is perpendicular to the upper surface of the substrate, a height of an upper surface of the buried pattern is greater than a height of an upper surface of the buried contact.

### CROSS-REFERENCE TO RELATED APPLICATION

This application claims priority from Korean Patent Application No. 10-2024-0060374 filed on May 8, 2024 in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor device and a method for manufacturing the semiconductor device. More specifically, the present disclosure relates to a semiconductor device including an alignment key and a method for manufacturing the same.

### BACKGROUND

As a semiconductor device becomes more highly integrated, a line width of a pattern included within the semiconductor device becomes smaller. As complex processes and new materials are applied, the difficulty of a measurement process thereof is also increasing.

An overlay measurement process is a process that determines an alignment state, that is, an overlay between a lower pattern and an upper pattern on a substrate. To precisely identify the overlay, an alignment key or an overlay key for each pattern may be used. However, the alignment key may be damaged due to introduction of the new materials or the complex manufacturing processes, and as a result, the difficulty of the overlay measurement is increasing.

### SUMMARY

Aspects of the present disclosure provide a semiconductor device having improved yield and productivity.

Additional aspects of the present disclosure provide a method for fabricating a semiconductor device having improved yield and productivity.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means illustrated in the claims and combinations thereof.

According to an aspect of the present disclosure, there is provided a semiconductor device comprising, a substrate that includes a first area and a second area, a first active pattern in the first area, a bit-line structure on the first area, a buried contact that is on a side surface of the bit-line structure and is electrically connected to the first active pattern of the first area, an alignment key structure that is on the second area and defines a key trench, and a buried pattern in at least a portion of the key trench, where the buried contact and the buried pattern include a first conductive material, and where, relative to an upper surface of the substrate and in a direction that is perpendicular to the upper surface of the substrate, a height of an upper surface of the buried pattern is greater than a height of an upper surface of the buried contact.

According to an aspect of the present disclosure, there is provided a semiconductor device comprising, a substrate that includes a chip area and a scribe lane area at least partially surrounding the chip area in plan view, a first active pattern in the chip area, a bit-line structure that is on the chip area, extends in a first direction, and is electrically connected to a first portion of the first active pattern, a buried contact that is on a side surface of the bit-line structure and is electrically connected to a second portion of the first active pattern, a gate electrode that extends in a second direction intersecting the first direction and extends between the first portion of the first active pattern and the second portion of the first active pattern, a capacitor structure that is on the bit-line structure and the buried contact and is electrically connected to the buried contact, an alignment key structure that is on the scribe lane area and includes a key trench, and a buried pattern in at least a portion of the key trench, where the bit-line structure and the alignment key structure include a first conductive material, where the buried contact and the buried pattern include a second conductive material, where, relative to an upper surface of the substrate and in a third direction that is perpendicular to the first direction and the second direction, a height of an upper surface of the buried pattern is greater than a height of an upper surface of the buried contact.

According to another aspect of the present disclosure, there is provided a method for manufacturing a semiconductor device, the method comprising, providing a substrate including a first area and a second area, sequentially forming a conductive film and a capping film on the first area and the second area, forming a bit-line structure on the first area and an alignment key structure on the second area by patterning the conductive film and the capping film, wherein the alignment key structure includes a key trench, forming a contact film covering the bit-line structure and the alignment key structure, forming a buried contact on a side surface of the bit-line structure and a buried pattern within the key trench by performing a first planarization process on the contact film, forming a mask pattern so as to cover the buried pattern and expose the buried contact, and performing an etch-back process on the buried contact using the mask pattern as an etch mask.

According to another aspect of the present disclosure, a semiconductor device includes a substrate that includes a chip area and a scribe area, a first active pattern in the chip area, a bit-line structure on the chip area, a buried contact that is on a side surface of the bit-line structure and is electrically connected to the first active pattern of the chip area, an alignment key structure that is on the scribe area and defines a key trench, and a buried pattern in at least a portion of the key trench, where, relative to an upper surface of the substrate and in a direction that is perpendicular to the upper surface of the substrate, a height of an upper surface of the buried pattern is greater than a height of an upper surface of the buried contact, and where the buried pattern is free of a silicide film.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail embodiments thereof with reference to the attached drawings, in which:

FIG. 1 is a plan view for illustrating a semiconductor device according to some embodiments.

FIG. 2 is a layout diagram for illustrating a first area, a second area, and a third area in FIG. 1.

FIG. 3 is a cross-sectional view cut along lines A1-A1, B-B, and C-C in FIG. 2.

FIG. 4 is a cross-sectional view cut along a line A2-A2 in FIG. 2.

FIG. 5 and FIG. 6 are various cross-sectional views for illustrating a semiconductor device according to some embodiments.

FIG. 7 to FIG. 33 are diagrams of intermediate structures corresponding to intermediate steps of a method for manufacturing a semiconductor device according to some embodiments.

### DETAILED DESCRIPTIONS

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction.

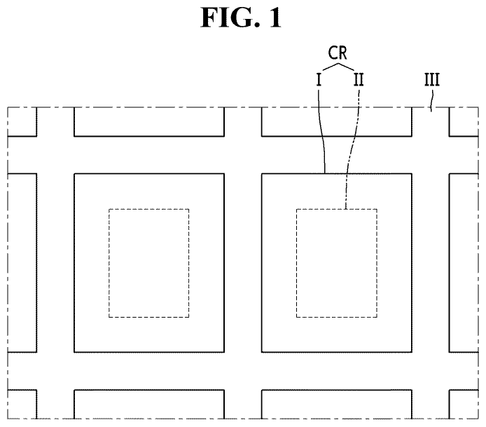

Hereinafter, with reference to FIG. 1 to FIG. 6, a semiconductor device according to some embodiments is described.

Although terms such as first, second, upper, and lower are used herein to describe various elements or components, it is obvious that these element or components are not limited by the terms. Rather, the terms are merely used herein to distinguish one element or component from another element or component. Therefore, a first element or component as mentioned below may also be a second element or component within the technical spirit of the present disclosure. Further, a lower element or component as mentioned below may also be an upper element or component within the technical spirit of the present disclosure.

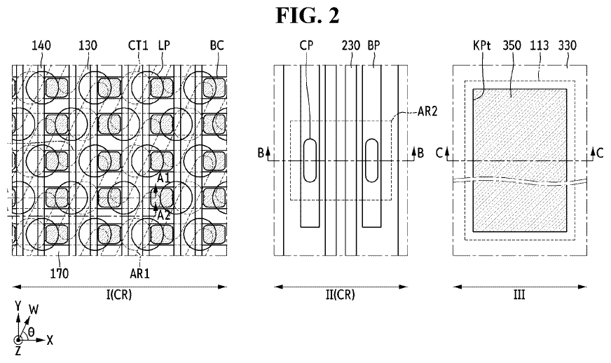

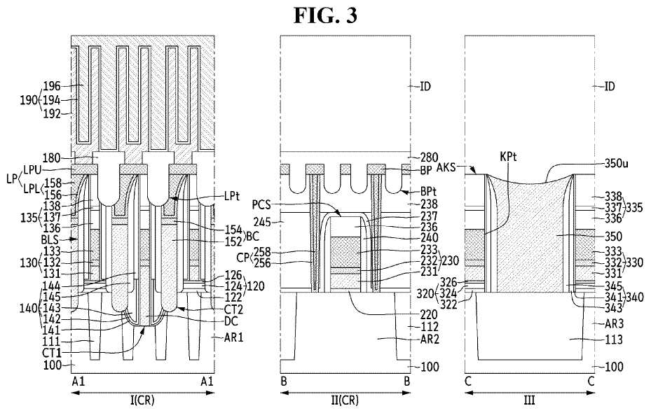

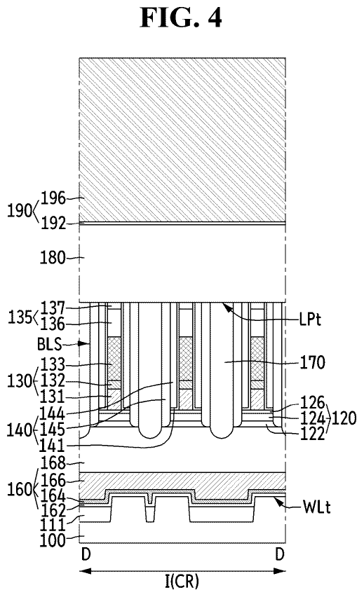

FIG. 1 is a plan view for illustrating a semiconductor device according to some embodiments. FIG. 2 is a layout diagram for illustrating a first area, a second area, and a third area in FIG. 1. FIG. 3 is a cross-sectional view cut along lines A1-A1, B-B, and C-C in FIG. 2. FIG. 4 is a cross-sectional view cut along a line A2-A2 in FIG. 2.

Referring to FIG. 1 to FIG. 4, the semiconductor device according to some embodiments includes a substrate 100, a bit-line structure BLS, a direct contact DC, a buried contact BC, a landing pad LP, a word-line structure 160, an insulating fence 170, a capacitor structure 190, a peripheral circuit structure PCS, an etch stop layer 237, a peripheral interlayer insulating film 245, a peripheral circuit capping film 238, a contact plug CP, a wiring pattern BP, an alignment key structure AKS, a buried pattern 350, and an upper insulating film ID.

The substrate 100 may be a semiconductor substrate such as a silicon wafer. The substrate 100 may have a structure in which a base substrate and an epitaxial layer are stacked. However, embodiments of the present disclosure are not limited thereto. The substrate 100 may be a silicon substrate, a gallium arsenide substrate, a silicon germanium substrate, or a SOI (semiconductor on insulator) substrate. Hereinafter, an example in which the substrate 100 is embodied as a silicon substrate is described.

The substrate 100 may include a first area I, a second area II, and a third area III.

The first area I may be a memory cell array area where memory cells are arranged. The second area II may be a core/peri area formed around the first area I. Some control elements and dummy elements may be formed on the second area II to control functions of memory cells formed on the first area I in plan view. The second area II is shown as being surrounded by the first area I. However, this is only an example, and the first area I and the second area II may be arranged in various forms.

The third area III may be a scribe lane area defining each of a plurality of chip areas CR. Each chip area CR may include the first area I and the second area II. The plurality of chip areas CR may be arranged two-dimensionally. The third area III may be formed between the chip areas CR. For example, the third area III may surround at least a portion of each chip area CR in plan view. After the semiconductor process on each chip area CR has been completed, the third area III may be cut to provide chip areas CR that are spaced apart from each other.

The substrate 100 may include a first active pattern AR1 in the first area I, a second active pattern AR2 in the second area II, and a third active pattern AR3 in the third area III.

The first active pattern AR1 may be defined by a first element isolation pattern 111 in the first area I of the substrate 100. The second active pattern AR2 may be defined by a second element isolation pattern 112 in the second area II of the substrate 100. The third active pattern AR3 may be defined by a third element isolation pattern 113 in the third area III of the substrate 100.

Each of the first element isolation pattern 111, the second element isolation pattern 112, and the third element isolation pattern 113 may include an insulating material, such as at least one of silicon oxide, silicon nitride, silicon oxynitride, silicon oxycarbonitride, and combinations thereof. However, embodiments of the present disclosure are not limited thereto. Each of the first element isolation pattern 111, the second element isolation pattern 112, and the third element isolation pattern 113 may be embodied as a single film made of a single type of an insulating material, or may be embodied as a stack of multiple films respectively made of several types of insulating materials.

Each of the first active patterns AR1 may be in a form of a plurality of bars extending in parallel with each other. In some embodiments, a center in a length direction of one of the plurality of the first active patterns AR1 may be disposed adjacent to each of both opposing ends in a length direction of another first active pattern AR1 adjacent thereto. In some embodiments, the first active pattern AR1 may be formed in a shape of a diagonal bar. For example, as shown in FIG. 2, the first active pattern AR1 may be in a form of a bar extending in a third direction W different from the first direction X and the second direction Y in a plane defined by the first direction X and the second direction Y.

A partial area of the first active pattern AR1 may include impurities and thus the area including the impurities may be provided as a source/drain area. For example, a first portion (e.g., a center portion) of the first active pattern AR1 may be connected to the bit-line structure BLS via the direct contact DC, and a second portion (each of both opposing ends) of the first active pattern AR1 may be connected to the capacitor structure 190 via the buried contact BC and/or the landing pad LP.

The bit-line structure BLS may be formed on the first area I. The bit-line structure BLS may extend in an elongated manner in the second direction Y and in a parallel manner to an upper surface of the substrate 100. For example, the bit-line structure BLS may extend to cross or intersect the first active pattern AR1 obliquely and extend across the word-line structure 160 in a perpendicular manner thereto. A plurality of bit-line structures BLS may be arranged so as to be spaced apart from each other and may extend in a parallel manner to each other and in the second direction Y. In some embodiments, the plurality of bit-line structures BLS may be spaced apart from each other by an equal spacing.

The bit-line structure BLS may include a first base insulating pattern 120, a first conductive pattern 130, a first capping pattern 135, and a first spacer structure 140. The first base insulating pattern 120, the first conductive pattern 130, and the first capping pattern 135 may be sequentially stacked on the first area I. The first spacer structure 140 may be formed on a side surface of the first base insulating pattern 120, a side surface of the first conductive pattern 130, and a side surface of the first capping pattern 135.

The first base insulating pattern 120 may extend in an elongated manner in the second direction Y and along an upper surface of the first active pattern AR1 and an upper surface of the first element isolation pattern 111. The first base insulating pattern 120 may be embodied as a single film, or may be embodied as a stack of multiple films as shown. For example, the first base insulating pattern 120 may include a first insulating line 122, a second insulating line 124, and a third insulating line 126 which are sequentially stacked on the first area I. For example, the first insulating line 122 may include a silicon oxide film. The second insulating line 124 may include a material having an etch selectivity different from that of the first insulating line 122. For example, the second insulating line 124 may include a silicon nitride film. The third insulating line 126 may include a material having a dielectric constant lower than that of the second insulating line 124. For example, the third insulating line 126 may include a silicon oxide film.

The first conductive pattern 130 may extend in an elongated manner in the second direction Y and along an upper surface of the first base insulating pattern 120. The first conductive pattern 130 may be embodied as a single film, or may be embodied as a stack of multiple films as shown. For example, the first conductive pattern 130 may include a first conductive line 131, a second conductive line 132, and a third conductive line 133 which are sequentially stacked on the first base insulating pattern 120. Each of the first conductive line 131, the second conductive line 132, and the third conductive line 133 may include a conductive material, such as at least one of polysilicon, TiN, TiSiN, tungsten, tungsten silicide, and combinations thereof. However, embodiments of the present disclosure are not limited thereto. For example, the first conductive line 131 may include a polysilicon (poly-Si) film, the second conductive line 132 may include a TiSiN film, and the third conductive line 133 may include a tungsten (W) film.

The first capping pattern 135 may extend in an elongated manner in the second direction Y and along the upper surface of the first conductive pattern 130. The first capping pattern 135 may be embodied as a single film, or may be embodied as a stack of multiple films as shown. For example, the first capping pattern 135 may include a first capping line 136, a second capping line 137, and a third capping line 138, which are sequentially stacked on the first conductive pattern 130. Each of the first capping line 136, the second capping line 137, and the third capping line 138 may include an insulating material, for example, at least one of silicon oxide, silicon nitride, silicon oxynitride, silicon oxycarbonitride, and combinations thereof. However, embodiments of the present disclosure are not limited thereto. For example, each of the first capping line 136, the second capping line 137, and the third capping line 138 may include a silicon nitride film.

The first spacer structure 140 may extend in an elongated manner in the second direction Y and along a side surface of the first base insulating pattern 120, a side surface of the first conductive pattern 130, and a side surface of the first capping pattern 135. In some embodiments, a vertical level of an upper surface of the first spacer structure 140 relative to a lower (or upper) surface of the substrate 100 may be equal to or lower than a vertical level of an uppermost surface of the first capping pattern 135 relative to the lower (or upper) surface of the substrate 100. For example, a vertical level of the upper surface of the first spacer structure 140 may decrease as a distance from the first capping pattern 135 increases. As used herein, “vertical level” refers to a level and/or height in a vertical direction (e.g., the fourth direction Z) relative to another surface, such as the lower or upper surface of the substrate 100.

The first spacer structure 140 may include an insulating material, at least one of, for example, silicon oxide, silicon nitride, silicon oxynitride, silicon oxycarbonitride, and combinations thereof. However, embodiments of the present disclosure are not limited thereto.

The direct contact DC may connect the first active pattern AR1 and the bit-line structure BLS to each other. For example, within the substrate 100, a first contact trench CT1 may be formed that extends through or into the first base insulating pattern 120 so as to expose the first portion (e.g., the center portion) of the first active pattern AR1. The direct contact DC may be formed within the first contact trench CT1 so as to electrically connect the first portion of the first active pattern AR1 and the first conductive pattern 130 to each other. The first conductive pattern 130 may be provided as a bit-line of the semiconductor memory device.

In some embodiments, the first spacer structure 140 may be embodied as a stack of multiple films respectively made of various types of insulating materials. For example, the first spacer structure 140 may include a first base spacer 141, a first lower spacer 142, a second lower spacer 143, a first side spacer 144, and a second side spacer 145.

The first base spacer 141 may extend along a side surface of the first conductive pattern 130, a side surface of the direct contact DC, and a side surface of the first capping pattern 135. In some embodiments, the first base spacer 141 may be an innermost spacer of the first spacer structure 140 in contact with the first conductive pattern 130, the direct contact DC, and the first capping pattern 135.

In some embodiments, the first base spacer 141 may extend further along an upper surface of the first base insulating pattern 120. In some embodiments, the first base spacer 141 may extend along the first contact trench CT1.

The first lower spacer 142 may be formed on the first base spacer 141 and within the first contact trench CT1. For example, the first lower spacer 142 may be conformally extended along a profile of the first base spacer 141 and within the first contact trench CT1.

The second lower spacer 143 may be formed on the first lower spacer 142 and within the first contact trench CT1. For example, the second lower spacer 143 may fill or be in an area of the first contact trench CT1 remaining after the first base spacer 141 and the first lower spacer 142 have been formed in the first contact trench CT1.

The first side spacer 144 may be formed on an outer side surface of the first base spacer 141. Moreover, the first side spacer 144 may be formed on an upper surface of the first lower spacer 142 and an upper surface of the second lower spacer 143.

The second side spacer 145 may be formed on an outer side surface of the first side spacer 144. Moreover, the second side spacer 145 may be formed on the upper surface of the second lower spacer 143. In some embodiments, the second side spacer 145 may be the outermost spacer of the first spacer structure 140 that contacts the buried contact BC and/or the landing pad LP. In some embodiments, a vertical level of the lowermost surface of the second side spacer 145 relative to the lower (or upper) surface of the substrate 100 may be lower than a vertical level of the uppermost surface of the second lower spacer 143 relative to the lower (or upper) surface of the substrate 100.

Each of the first base spacer 141, the first lower spacer 142, the second lower spacer 143, the first side spacer 144 and the second side spacer 145 may include an insulating material, for example, at least one silicon oxide, silicon nitride, silicon oxynitride, silicon oxycarbonitride, and combinations thereof. However, embodiments of the present disclosure are not limited thereto.

In some embodiments, the first lower spacer 142 may include a material with a lower dielectric constant than that of the first base spacer 141 and/or the second lower spacer 143. For example, the first lower spacer 142 may include a silicon oxide film, and each of the first base spacer 141 and the second lower spacer 143 may include a silicon nitride film.

In some embodiments, the first side spacer 144 may include a material with a lower dielectric constant than that of the first base spacer 141 and/or the second side spacer 145. For example, the first side spacer 144 may include a silicon oxide film, and each of the first base spacer 141 and the second side spacer 145 may include a silicon nitride film.

The buried contact BC may be formed on the first area I. The buried contact BC may be connected to the first active pattern AR1. For example, within the substrate 100, a second contact trench CT2 may be formed that extends through the first base insulating pattern 120 so as to expose the second portion (e.g., each of both opposing ends) of the first active pattern AR1. The buried contact BC may be formed in the second contact trench CT2 and may be electrically connected to the second portion of the first active pattern AR1.

The buried contact BC may be formed on a side surface of the bit-line structure BLS. Moreover, the buried contact BC may be spaced apart from the first conductive pattern 130 via the first spacer structure 140. For example, as shown in FIG. 3, the buried contact BC may extend along a portion of an outer side surface of the first spacer structure 140. In some embodiments, relative to the upper or lower surface of the substrate 100, a level of the upper surface of the buried contact BC in the fourth direction Z may be lower than a level of the upper surface of the first capping pattern 135 in the fourth direction Z. Adjacent ones of the plurality of buried contacts BC arranged along the first direction X may be isolated from each other via each of the plurality of bit-line structures BLS extending in a parallel manner with each other and in the second direction Y.

The buried contact BC may include a conductive material such as at least one of polysilicon, TiN, TiSiN, tungsten, tungsten silicide, and combinations thereof. However, embodiments of the present disclosure are not limited thereto. For example, the buried contact BC may include a polysilicon (poly-Si) film.

In some embodiments, the buried contact BC may include a first filling conductive film 152 and a silicide film 154.

The first filling conductive film 152 may fill or be in the second contact trench CT2. The first filling conductive film 152 may extend along a portion of the side surface of the bit-line structure BLS. The first filling conductive film 152 may include a conductive semiconductor material film, for example, a poly-silicon (poly-Si) film doped with impurities.

The silicide film 154 may be interposed between the first filling conductive film 152 and the landing pad LP. The silicide film 154 may be formed by reacting silicon (Si) included in the first filling conductive film 152 with a metal element (e.g., a metal element included in the landing pad LP). The silicide film 154 may include metal silicide such as nickel silicide, cobalt silicide, tungsten silicide, titanium silicide, niobium silicide, or tantalum silicide. However, embodiments of the present disclosure are not limited thereto.

The landing pad LP may be formed on an upper surface of the buried contact BC. The landing pad LP may be electrically connected to the buried contact BC. In some embodiments, the landing pad LP may overlap the bit-line structure BLS and the buried contact BC in the fourth direction Z. For example, a portion of the landing pad LP may overlap the buried contact BC, and the other portion of the landing pad LP may overlap a portion of the first capping pattern 135 and a portion of the first spacer structure 140 in the fourth direction Z. In this regard, overlapping means overlap in the fourth direction Z that intersects the upper surface of the substrate 100.

The landing pad LP may include a conductive material such as at least one of polysilicon, TiN, TiSiN, tungsten, tungsten silicide, and combinations thereof. However, embodiments of the present disclosure are not limited thereto. For example, the landing pad LP may include tungsten (W).

The landing pad LP may be formed as each of a plurality of isolated areas that are spaced apart from each other. For example, a pad trench LPt may be formed to define each of a plurality of landing pads LP that are spaced apart from each other. The pad trench LPt may extend from an upper surface of the landing pad LP. Relative to the lower (or upper) surface of the substrate 100, a level of a lower surface of the pad trench LPt in the fourth direction Z may be lower than a level of the upper surface of the first capping pattern 135 in the fourth direction Z and may be higher than a level of the upper surface of the first conductive pattern 130. In some embodiments, a portion of the pad trench LPt may overlap the first capping pattern 135 and the first spacer structure 140 in the fourth direction Z.

In some embodiments, a first isolation pattern 180 may be formed to fill or be in the pad trench LPt. The first isolation pattern 180 may include an insulating material, such as at least one of silicon oxide, silicon oxynitride, silicon nitride, and a low-k material with a dielectric constant smaller than that of silicon oxide. However, the technical idea of the present disclosure is not limited thereto. The plurality of landing pads LP may be electrically insulated from each other via the first isolation pattern 180.

In some embodiments, the plurality of landing pads LP may be arranged in a honeycomb structure. The landing pads LP arranged in the honeycomb structure may further improve an integration density of the semiconductor memory device.

In some embodiments, the landing pad LP may include a lower pad LPL and an upper pad LPU.

The lower pad LPL may be formed on the upper surface of the buried contact BC and the side surface of the bit-line structure BLS. For example, the lower pad LPL may fill or be in a space on the upper surface of the buried contact BC and the side surface of a bit-line structure BLS. Relative to the lower (or upper) surface of the substrate 100, a level of the uppermost surface of the lower pad LPL in the fourth direction Z may be equal to or lower than a level of the uppermost surface of the first capping pattern 135 in the fourth direction Z. In some embodiments, relative to the upper or lower surface of the substrate 100, a level of the uppermost surface of the lower pad LPL in the fourth direction Z may be equal to a level of the uppermost surface of the first capping pattern 135 in the fourth direction Z. Adjacent ones of A plurality of lower pads LPL arranged along the first direction X may be isolated from each other via each of the plurality of bit-line structures BLS extending in a parallel manner to each other and in the second direction Y. As used herein, “being equal to” means not only being exactly equal to but also including a minor difference that may occur due to a process margin, etc.

In some embodiments, the lower pad LPL may include a first barrier conductive film 156 and a first filling metal film 158.

The first barrier conductive film 156 may extend conformally along a profile of the upper surface of the buried contact BC and the side surface of the first spacer structure 140. In some embodiments, relative to the lower (or upper) surface of the substrate 100, a level of the uppermost surface of the first barrier conductive film 156 in the fourth direction D4 may be equal to a level of the uppermost surface of the bit-line structure BLS in the fourth direction D4. The first barrier conductive film 156 may include a metal or metal nitride to prevent or inhibit diffusion of a metal element included in the first filling metal film 158. For example, the first barrier conductive film 156 may include at least one of titanium (Ti), tantalum (Ta), tungsten (W), nickel (Ni), cobalt (Co), platinum (Pt), alloys thereof, and nitrides thereof. However, embodiments of the present disclosure are not limited thereto. In one example, the first barrier conductive film 156 may include a titanium nitride (TiN) film.

The first filling metal film 158 may be formed on the first barrier conductive film 156. The first filling metal film 158 may fill or be in a space on the upper surface of the buried contact BC and the side surface of the bit-line structure BLS. The first filling metal film 158 may include a conductive metal, for example, tungsten (W).

The upper pad LPU may be formed on an upper surface of the lower pad LPL and the upper surface of the bit-line structure BLS. Adjacent ones of a plurality of upper pads LPU may be isolated from each other via the pad trench LPt. In some embodiments, the upper pad LPU may contact the upper surface of the first barrier conductive film 156 and the upper surface of the first filling metal film 158.

The upper pad LPU may include a conductive material such as at least one of polysilicon, TiN, TiSiN, tungsten, tungsten silicide, and combinations thereof. However, embodiments of the present disclosure are not limited thereto. In some embodiments, the upper pad LPU may include the same conductive metal as that of the first filling metal film 158. For example, the landing pad LP may include tungsten (W).

It is shown that a boundary is formed between the lower pad LPL and the upper pad LPU. However, this is only an example. Alternatively, depending on a process of forming the lower pad LPL and the upper pad LPU, the boundary may not be formed between the lower pad LPL and the upper pad LPU.

The word-line structure 160 may be formed on the first area I. The word-line structure 160 may extend in an elongated manner in the first direction X and in a parallel manner to the upper surface of the substrate 100. For example, the word-line structure 160 may extend across the first active pattern AR1 in an oblique manner and extend across the bit-line structure BLS in a perpendicular manner thereto.

A plurality of word-line structures 160 may be spaced apart from each other and extend in a parallel manner to each other and in the first direction X. In some embodiments, the plurality of word-line structures 160 may be equally spaced apart from each other.

The word-line structure 160 may extend across a portion of the first active pattern AR1 between the direct contact DC and the buried contact BC. For example, the word-line structure 160 may extend across a portion of the first active pattern AR1 between the first portion (e.g., the center portion) of the first active pattern AR1 and the second portion (e.g., each of both opposing ends) of the first active pattern AR1.

In some embodiments, two word-line structures 160 may extend across one first active pattern AR1. For example, two word-line structures 160 may be respectively disposed on both opposing sides of the direct contact DC. These two word-line structures 160 may share one direct contact DC.

The word-line structure 160 may include a first gate dielectric film 162, a first gate electrode 164 and 166, and a first gate capping film 168. The first gate dielectric film 162, the first gate electrode 164 and 166, and the first gate capping film 168 may be sequentially stacked on the first area I.

The first gate dielectric film 162 may be interposed between the first active pattern AR1 and the first gate electrode 164 and 166. For example, the first gate dielectric film 162 may extend in an elongated manner in the first direction X while being disposed on the first active pattern AR1 and the first element isolation pattern 111. The first gate dielectric film 162 may include, but is limited to, at least one of, for example, silicon oxide, silicon oxynitride, silicon nitride, and a high-k material with a dielectric constant greater than that of silicon oxide.

The first gate electrode 164 and 166 may extend in an elongated manner in the first direction X while being disposed on the first gate dielectric film 162. The first gate electrode 164 and 166 may be embodied as a single film, or may be embodied as a stack of multiple films as shown. For example, the first gate electrode 164 and 166 may include the first gate pattern 164 and the second gate pattern 166 which are sequentially stacked on the first gate dielectric film 162. Each of the first gate pattern 164 and the second gate pattern 166 may include a conductive material such as at least one of, for example, polysilicon, TiN, TiSiN, tungsten, tungsten silicide, and combinations thereof. However, the technical idea of the present disclosure is not limited thereto.

The first gate electrode 164 and 166 may be provided as a word-line of the semiconductor memory device. The first portion (e.g., the central portion) of the first active pattern AR1 may be provided as a first source/drain area of a field effect transistor using the first gate electrode 164 and 166 as a gate electrode. The second portion (e.g., each of both opposing ends) of the first active pattern AR1 may be provided as a second source/drain area of the field effect transistor using the first gate electrode 164 and 166 as the gate electrode.

The first gate capping film 168 may extend in an elongated manner in the first direction X and along the upper surface of the first gate electrode 164 and 166. The first gate capping film 168 may include an insulating material, at least one of, for example, silicon oxide, silicon nitride, silicon oxynitride, silicon oxycarbonitride, and a combination thereof. However, embodiments of the present disclosure are not limited thereto. The first gate capping film 168 may be embodied as a single film or a stack of multiple films respectively made of various types of insulating materials.

In some embodiments, the word-line structure 160 may be buried within the substrate 100. For example, a gate trench WLt extending in the first direction X may be formed within the first active pattern AR1 and the first element isolation pattern 111. The first gate dielectric film 162 may extend along a profile of the gate trench WLt. The first gate electrode 164 and 166 may fill or be in a portion of the gate trench WLt while being disposed on the first gate dielectric film 162. The first gate capping film 168 may fill another portion of the gate trench WLt while being disposed on the first gate dielectric film 162 and the first gate electrode 164 and 166. In this case, relative to the lower (or upper) surface of the substrate 100, a level of an upper surface of the first gate electrode 164 and 166 in the fourth direction Z may be lower than a level of the upper surface of the substrate 100 in the fourth direction Z.

An insulating fence 170 may be formed on the first area I. The insulating fence 170 may be formed on an upper surface of the word-line structure 160 and the side surface of the bit-line structure BLS. The first isolation pattern 180 may be formed on an upper surface of the insulating fence 170. In some embodiments, relative to the lower (or upper) surface of the substrate 100, a level of the upper surface of the insulating fence 170 in the fourth direction Z may be higher than a level of the upper surface of the buried contact BC in the fourth direction Z. Adjacent ones of the plurality of buried contacts BC arranged along the second direction Y may be isolated from each other via each of the insulating fences 170 extending in a parallel manner to each other and in the first direction X. For example, the plurality of bit-line structures BLS and the plurality of insulating fences 170 may define a plurality of isolated areas arranged in a lattice structure therebetween. The buried contacts BC may be respectively formed within the isolated areas and thus may be isolated from each other.

The insulating fence 170 may include an insulating material, at least one of, for example, silicon oxide, silicon nitride, silicon oxynitride, silicon oxycarbonitride, and combinations thereof. However, embodiments of the present disclosure are not limited thereto. For example, the insulating fence 170 may include a silicon nitride film.

The capacitor structure 190 may be formed on the first isolation pattern 180 and the landing pad LP. The capacitor structure 190 may be electrically connected to the landing pad LP. For example, the first isolation pattern 180 may be patterned such that at least a portion of the upper surface of the landing pad LP is exposed. The capacitor structure 190 may be connected to at least a portion of the upper surface of the landing pad LP exposed by the first isolation pattern 180.

The capacitor structure 190 may be controlled by the first conductive pattern 130 provided as the bit-line and the first gate electrode 164 and 166 provided as the word-line to store therein data. In some embodiments, the capacitor structure 190 may include a lower electrode 192, a capacitor dielectric film 194, and an upper electrode 196 that are sequentially stacked on the landing pad LP. The capacitor structure 190 may store charges in the capacitor dielectric film 194 using a difference between a potential of the lower electrode 192 and a potential of the upper electrode 196.

The lower electrode 192 and the upper electrode 196 may include, for example, doped polysilicon, metal, or metal nitride. However, embodiments of the present disclosure are not limited thereto. Moreover, the capacitor dielectric film 194 may include, for example, silicon oxide or a high dielectric constant material. However, embodiments of the present disclosure are not limited thereto.

The peripheral circuit structure PCS may be formed on the second area II. The peripheral circuit structure PCS may be formed on the second active pattern AR2. The peripheral circuit structure PCS may control a function of the memory cells formed on the first area I. The peripheral circuit structure PCS may include various active elements such as transistors, as well as various passive elements such as capacitors, resistors, and inductors. The peripheral circuit structure PCS is shown as extending in the second direction Y. However, this is only an example. In another example, the peripheral circuit structure PCS may extend in various other directions.

In some embodiments, the peripheral circuit structure PCS may include a second gate dielectric film 220, a second gate electrode 230, a second gate capping film 236, and a gate spacer 240. The second gate dielectric film 220, the second gate electrode 230, and the second gate capping film 236 may be sequentially stacked on the second area II. The gate spacer 240 may be formed on a side surface of the second gate dielectric film 220, a side surface of the second gate electrode 230, and a side surface of the second gate capping film 236.

The second gate dielectric film 220 may be interposed between the second active pattern AR2 and the second gate electrode 230. For example, the second gate dielectric film 220 may extend along an upper surface of the second active pattern AR2 and/or an upper surface of the second element isolation pattern 112. The second gate dielectric film 220 may include, but is limited to, at least one of, for example, silicon oxide, silicon oxynitride, silicon nitride, and a high-k material with a dielectric constant greater than that of silicon oxide.

The second gate electrode 230 may be formed on an upper surface of the second gate dielectric film 220. The second gate electrode 230 may be embodied as a single film, or may be embodied as a stack of multiple films as shown. For example, the second gate electrode 230 may include a third gate pattern 231, a fourth gate pattern 232, and a fifth gate pattern 233 that are sequentially stacked on the second gate dielectric film 220.

In some embodiments, the second gate electrode 230 may be formed at the same level as the first conductive pattern 130. As used herein, “being formed at the same level” means “being formed in the same manufacturing process”. For example, components formed at the same level may have the same material composition. Alternatively, for example, components formed at the same level may have the same thickness. For example, the second gate electrode 230 may include the same conductive material or the same material composition as that of the first conductive pattern 130. Alternatively, in an example, the thickness of the second gate electrode 230 may be equal to as the thickness of the first conductive pattern 130.

The second gate capping film 236 may extend along the upper surface of the second gate electrode 230. The second gate capping film 236 may include an insulating material, at least one of, for example, silicon oxide, silicon nitride, silicon oxynitride, silicon oxycarbonitride, and combinations thereof. However, embodiments of the present disclosure are not limited thereto. In some embodiments, the second gate capping film 236 may be formed at the same level as the first capping line 136.

The gate spacer 240 may extend along a side surface of the second gate dielectric film 220, a side surface of the second gate electrode 230, and a side surface of the second gate capping film 236. The gate spacer 240 may include an insulating material, at least one of, for example, silicon oxide, silicon nitride, silicon oxynitride, silicon oxycarbonitride, and combinations thereof. However, embodiments of the present disclosure are not limited thereto.

The etch stop layer 237 may be formed on the second area II. The etch stop layer 237 may cover or be on the peripheral circuit structure PCS. For example, the etch stop layer 237 may conformally extend along the upper surface of the second active pattern AR2, the upper surface of the second element isolation pattern 112, and side and upper surfaces of the peripheral circuit structure PCS. In some embodiments, the etch stop layer 237 may be formed at the same level as the second capping line 137.

The peripheral interlayer insulating film 245 may be formed on the etch stop layer 237. The peripheral interlayer insulating film 245 may fill or be in a space on the upper surface of the substrate 100 and the side surface of the peripheral circuit structure PCS. The peripheral interlayer insulating film 245 may include an insulating material such as at least one of silicon oxide, silicon oxynitride, silicon nitride, and a low-k material with a dielectric constant lower than that of silicon oxide. However, embodiments of the present disclosure are not limited thereto.

The peripheral circuit capping film 238 may be formed on the etch stop layer 237 and the peripheral interlayer insulating film 245. For example, the peripheral circuit capping film 238 may extend along the upper surface of the etch stop layer 237 and the upper surface of the peripheral interlayer insulating film 245. In some embodiments, relative to the lower (or upper) surface of the substrate 100, a level of the upper surface of the peripheral circuit capping film 238 in the fourth direction Z may be equal to a level of the upper surface of the first capping pattern 135 in the fourth direction Z.

The peripheral circuit capping film 238 may include an insulating material, at least one of, for example, silicon oxide, silicon nitride, silicon oxynitride, silicon oxycarbonitride, and combinations thereof. However, embodiments of the present disclosure are not limited thereto.

The contact plug CP may be formed on the side surface of the peripheral circuit structure PCS. The contact plug CP may be connected to the second active pattern AR2. For example, the contact plug CP may extend in the fourth direction Z. The contact plug CP may be connected to the second active pattern AR2 by sequentially penetrating or extending into the peripheral circuit capping film 238, the peripheral interlayer insulating film 245, and the etch stop layer 237.

In some embodiments, the contact plug CP may be formed at the same level as the lower pad LPL. In some embodiments, the contact plug CP may include a second barrier conductive film 256 and a second filling metal film 258. In some embodiments, the second barrier conductive film 256 may be formed at the same level as the first barrier conductive film 156, and the second filling metal film 258 may be formed at the same level as the first filling metal film 158.

The wiring pattern BP may form a plurality of wirings that are spaced apart from each other. For example, a wiring trench BPt may be formed to define each of a plurality of wiring patterns BP that are spaced apart from each other. The wiring trench BPt may extend from an upper surface of the wiring pattern BP. Relative to the lower (or upper) surface of the substrate 100, a level of a lower surface of the wiring trench BPt in the fourth direction Z may be lower than a level of the upper surface of the peripheral circuit capping film 238 in the fourth direction Z and may be higher than that of the upper surface of the second gate electrode 230 in the fourth direction Z. In some embodiments, the wiring pattern BP may be formed at the same level as the upper pad LPU.

In some embodiments, a second isolation pattern 280 may be formed to fill or be in the wiring trench BPt. The plurality of wiring patterns BP may be electrically insulated from each other via the second isolation pattern 280. In some embodiments, the second isolation pattern 280 may be formed at the same level as the first isolation pattern 180.

At least some of the plurality of wiring patterns BP may be connected to the contact plug CP. Each wiring pattern BP is shown as extending in the second direction Y. However, this is only an example. In another example, each wiring pattern BP may extend in various other directions.

The alignment key structure AKS may be formed on the third area III. The alignment key structure AKS may define a key trench KPt. For example, the key trench KPt may be defined by an inner side surface of the alignment key structure AKS. In FIG. 2, the key trench KPt is shown to extend in an elongated manner in the second direction Y. However, this is only an example, and the key trench KPt may extend in another direction (e.g., the first direction X).

In some embodiments, the key trench KPt may overlap the third element isolation pattern 113 in the fourth direction Z. For example, a lower surface of the key trench KPt may be defined by an upper surface of the third element isolation pattern 113. The key trench KPt is shown extending in the second direction Y. However, this is only an example, and the key trench KPt may extend in various other directions.

The alignment key structure AKS may include a second base insulating pattern 320, a second conductive pattern 330, a second capping pattern 335, and a second spacer structure 340. The second base insulating pattern 320, the second conductive pattern 330, and the second capping pattern 335 may be sequentially stacked on the third area III. The second spacer structure 340 may be formed on a side surface of the second base insulating pattern 320, a side surface of the second conductive pattern 330, and a side surface of the second capping pattern 335.

In some embodiments, the alignment key structure AKS may be formed at the same level as the bit-line structure BLS. For example, a thickness of the alignment key structure AKS in the fourth direction Z may be equal to the thickness of the bit-line structure BLS in the fourth direction Z. In some embodiments, relative to the upper (or lower) surface of the substrate 100, a level of the upper surface of the alignment key structure AKS in the fourth direction Z may be equal to a level of the upper surface of the bit-line structure BLS in the fourth direction Z.

The second base insulating pattern 320 may extend along an upper surface of the third active pattern AR3 and/or an upper surface of the third element isolation pattern 113. The second base insulating pattern 320 may be embodied as a single film, or may be embodied as a stack of multiple films as shown. For example, the second base insulating pattern 320 may include a fourth insulating line 322, a fifth insulating line 324, and a sixth insulating line 326 that are sequentially stacked on the third area III. In some embodiments, the second base insulating pattern 320 may be formed at the same level as the first base insulating pattern 120.

The second conductive pattern 330 may extend along the upper surface of the second base insulating pattern 320. The second conductive pattern 330 may be embodied as a single film, or may be embodied as a stack of multiple films as shown. For example, the second conductive pattern 330 may include a fourth conductive line 331, a fifth conductive line 332, and a sixth conductive line 333 that are sequentially stacked on the second base insulating pattern 320. In some embodiments, the second conductive pattern 330 may be formed at the same level as the first conductive pattern 130.

The second capping pattern 335 may extend along the upper surface of the second conductive pattern 330. The first capping pattern 135 may be embodied as a single film, or may be embodied as a stack of multiple films as shown. For example, the second capping pattern 335 may include a fourth capping line 336, a fifth capping line 337, and a sixth capping line 338 that are sequentially stacked on the second conductive pattern 330. In some embodiments, the second capping pattern 335 may be formed at the same level as the first capping pattern 135.

The second spacer structure 340 may extend along a side surface of the second base insulating pattern 320, a side surface of the second conductive pattern 330, and a side surface of the second capping pattern 335. In some embodiments, a vertical level of the upper surface of the second spacer structure 340 may be equal to or lower than a vertical level of the uppermost surface of the second capping pattern 335. For example, relative to the upper (or lower) surface of the substrate 100, the level of the upper surface of the second spacer structure 340 in the fourth direction Z may decrease as a distance from the second capping pattern 335 increases in the first direction X.

The second spacer structure 340 may include an insulating material, at least one of, for example, silicon oxide, silicon nitride, silicon oxynitride, silicon oxycarbonitride, and combinations thereof. However, embodiments of the present disclosure are not limited thereto.

In some embodiments, the second spacer structure 340 may be embodied as a stack of multiple films respectively made of various types of insulating materials. For example, the second spacer structure 340 may include a second base spacer 341, a third side spacer 344, and a fourth side spacer 345. In some embodiments, the second base spacer 341 may be formed at the same level as the first base spacer 141. In some embodiments, the third side spacer 344 may be formed at the same level as the first side spacer 144. In some embodiments, the fourth side spacer 345 may be formed at the same level as the second side spacer 145.

The buried pattern 350 may fill at least portion of or be in the key trench KPt. For example, the buried pattern 350 may contact an upper surface of the third element isolation pattern 113. The buried pattern 350 may include the same conductive material as that of the buried contact BC. For example, the buried pattern 350 may include a polysilicon (poly-Si) film.

The buried pattern 350 may be formed at the same level as the buried contact BC. In some embodiments, the buried pattern 350 may be formed at the same level as the first filling conductive film 152. For example, each of the first filling conductive film 152 and the buried pattern 350 may be embodied as a film made of polysilicon (poly-Si) doped with impurities. In some embodiments, the buried pattern 350 may not include a silicide, such as a silicide film (i.e., the buried pattern 350 is free of a silicide film).

Relative to the upper (or lower) surface of the substrate 100, a level of the upper surface of the buried pattern 350 in the fourth direction Z may be higher than a level of the upper surface of the buried contact BC in the fourth direction Z. For example, relative to the lower (or upper) surface of the substrate 100, a level of the uppermost surface of the buried contact BC in the fourth direction Z may be lower than a level of the upper surface of the bit-line structure BLS in the fourth direction Z. Relative to the lower (or upper) surface of the substrate 100, a level of the uppermost surface of the buried pattern 350 in the fourth direction Z may be equal to a level of an upper surface of the alignment key structure AKS in the fourth direction Z.

In some embodiments, the upper surface of the buried pattern 350 may be continuous with (or directly contact) the upper surface of the alignment key structure AKS. For example, at a boundary between the upper surface of the alignment key structure AKS and the upper surface of the buried pattern 350, relative to the lower (or upper) surface of the substrate 100, a level of the upper surface of the alignment key structure AKS in the fourth direction Z and a level of the upper surface of the buried pattern 350 in the fourth direction Z may be equal to each other.

In some embodiments, the buried pattern 350 may entirely cover or overlap an outer side surface of the second spacer structure 340 in the first direction X.

In some embodiments, the upper surface of the buried pattern 350 may include a first concave surface 350u having a concave shape.

The upper insulating film ID may be formed on the second area II and the third area III. The upper insulating film ID may cover or be on the upper surface of the second isolation pattern 280, the upper surface of the alignment key structure AKS, and the upper surface of the buried pattern 350. The upper insulating film ID may include an insulating material such as at least one of silicon oxide, silicon oxynitride, silicon nitride, and a low-k material with a dielectric constant lower than that of silicon oxide. However, embodiments of the present disclosure are not limited thereto.

In some embodiments, the upper insulating film ID may contact the upper surface of the alignment key structure AKS and the upper surface of the buried pattern 350. In some embodiments, the upper insulating film ID may contact the first concave surface 350u of the buried pattern 350.

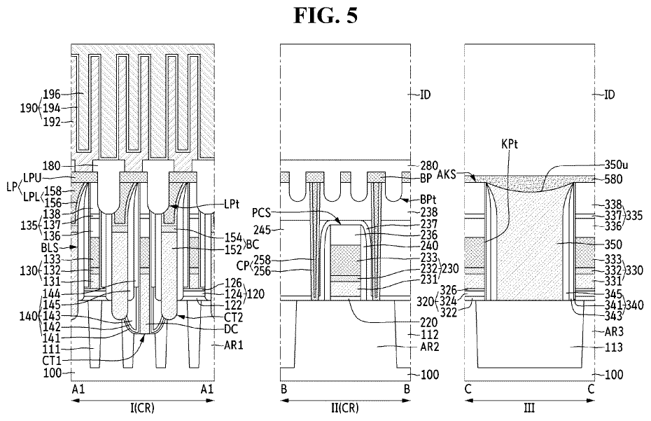

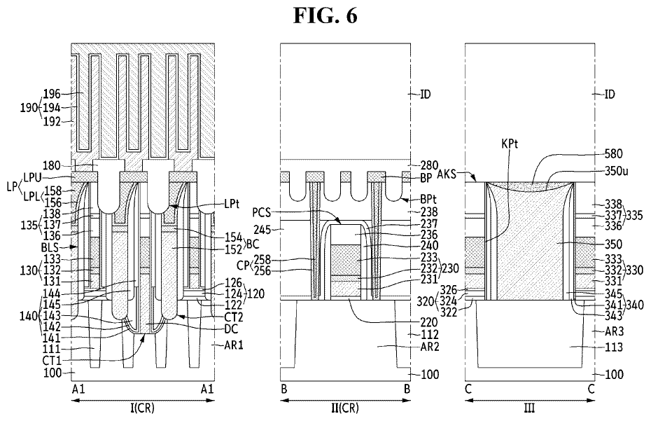

FIG. 5 and FIG. 6 are various cross-sectional views for illustrating a semiconductor device according to some embodiments. For convenience of description, components duplicate with those as described above using FIG. 1 to FIG. 4 are briefly described or descriptions thereof are omitted.

Referring to FIG. 1, FIG. 2, and FIG. 5, the semiconductor device according to some embodiments further includes a mask pattern 580.

The mask pattern 580 may be formed on the third area III. The mask pattern 580 may not be formed on the first area I and the second area II. For example, in the fourth direction Z, the mask pattern 580 may overlap at least a portion of the third area III and may not overlap (e.g., free from overlap) the first area I and the second area II.

In some embodiments, the mask pattern 580 may contact and at least partially overlap the upper surface of the alignment key structure AKS and the upper surface of the buried pattern 350. In some embodiments, the mask pattern 580 may contact the first concave surface 350u of the buried pattern 350.

Referring to FIG. 1, FIG. 2, and FIG. 6, in the semiconductor device according to some embodiments, the mask pattern 580 exposes the upper surface of the alignment key structure AKS.

For example, relative to the lower (or upper) surface of the substrate 100, a level of the upper surface of the mask pattern 580 in the fourth direction Z may be equal to or lower than a level of the upper surface of the alignment key structure AKS in the fourth direction. In some embodiments, relative to the lower (or upper) surface of the substrate 100, a level of the upper surface of the mask pattern 580 in the fourth direction Z may be equal to a level of the upper surface of the alignment key structure AKS in the fourth direction Z.

In some embodiments, the upper insulating film ID may contact the upper surface of the alignment key structure AKS, and the mask pattern 580 may contact the upper surface of the buried pattern 350.

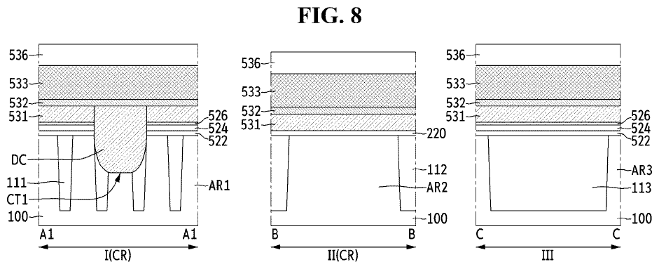

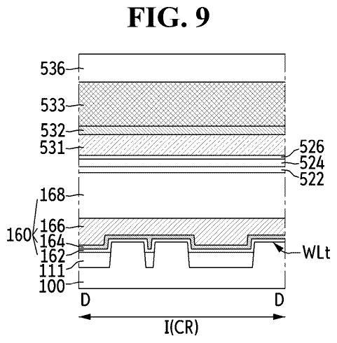

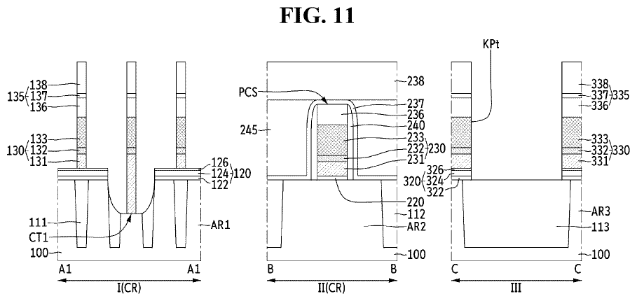

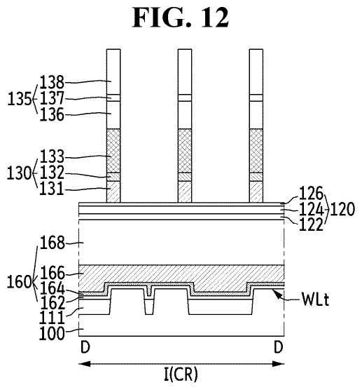

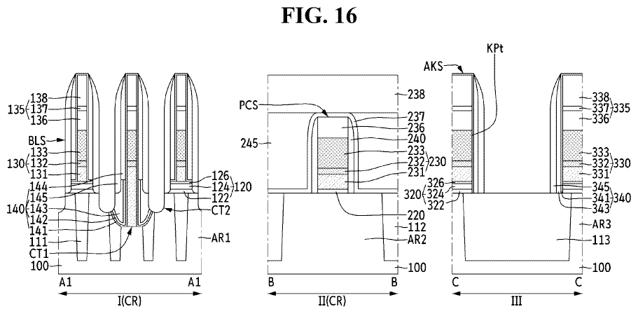

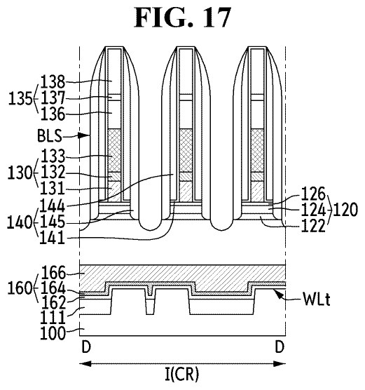

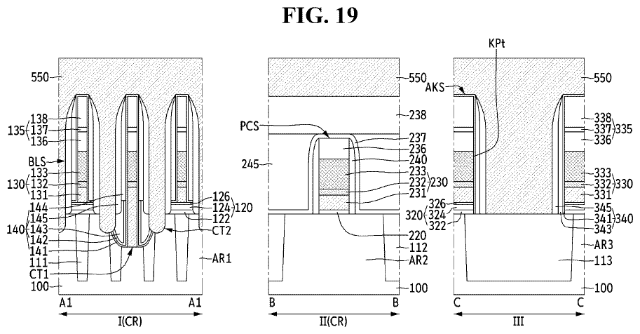

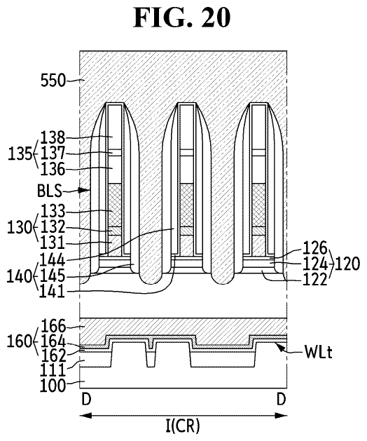

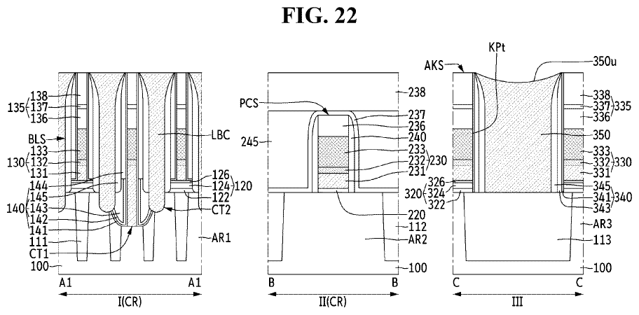

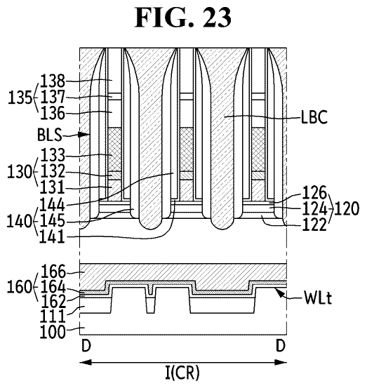

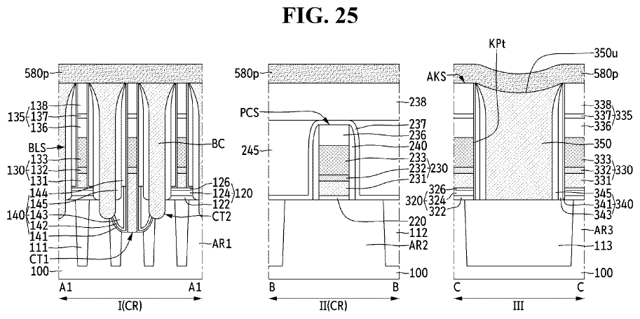

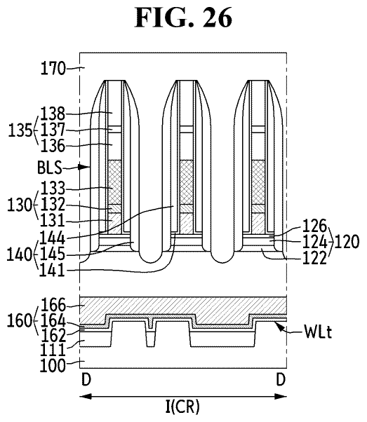

Hereinafter, with reference to FIG. 1 to FIG. 33, a method for manufacturing a semiconductor memory device according to some embodiments is described.

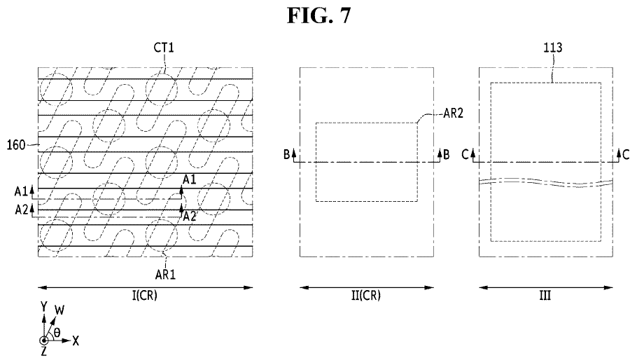

FIG. 7 to FIG. 33 are diagrams of intermediate structures corresponding to intermediate steps of a method for manufacturing a semiconductor device according to some embodiments. For convenience of description, components that are the same as those described above using FIG. 1 to FIG. 6 are briefly described or descriptions thereof are omitted.

Referring to FIG. 7 to FIG. 9, the word-line structure 160, the first to third insulating films 522, 524, and 526, the second gate dielectric film 220, the first to third conductive films 531, 532, and 533, the direct contact DC and the first capping film 536 are formed on the substrate 100.

The substrate 100 may include the first active pattern AR1 in the first area I, the second active pattern AR2 in the second area II, and the third active pattern AR3 in the third area III.

The word-line structure 160 may be formed on the first area I. The word-line structure 160 may extend in an elongated manner in the first direction X. In some embodiments, word-line structure 160 may be buried within the substrate 100. For example, the gate trench WLt extending in the first direction X may be formed within the first active pattern AR1 and the first element isolation pattern 111. The word-line structure 160 may be formed within the gate trench WLt.

The first to third insulating films 522, 524, and 526 may be formed on the first area I and the third area III, and the second gate dielectric film 220 may be formed on the second area II. The first insulating film 522 and the second gate dielectric film 220 may be formed at the same level. However, embodiments of the present disclosure are not limited thereto.

Subsequently, the first conductive film 531 may be formed on the third insulating film 526 and the second gate dielectric film 220. Moreover, within the first area I, the first contact trench CT1 that exposes the first portion (e.g., the center portion) of the first active pattern AR1 may be formed. The direct contact DC may fill or be in the first contact trench CT1.

Subsequently, the second conductive film 532, the third conductive film 533, and the first capping film 536 may be formed sequentially on the first conductive film 531 and the direct contact DC.

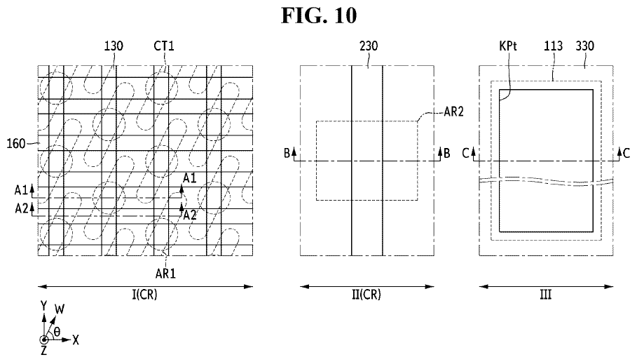

Referring to FIG. 10 to FIG. 12, the first base insulating pattern 120, the first conductive pattern 130, the first capping pattern 135, the peripheral circuit structure PCS, the etch stop layer 237, the peripheral interlayer insulating film 245, the peripheral circuit capping film 238, the second base insulating pattern 320, the second conductive pattern 330, and the second capping pattern 335 are formed.

The first base insulating pattern 120, the first conductive pattern 130, and the first capping pattern 135 may be formed on the first area I. The peripheral circuit structure PCS, the etch stop layer 237, the peripheral interlayer insulating film 245, and the peripheral circuit capping film 238 may be formed on the second area II. The second base insulating pattern 320, the second conductive pattern 330, and the second capping pattern 335 may be formed on the third area III.

The first base insulating pattern 120 and the second base insulating pattern 320 may be formed by patterning the first to third insulating films 522, 524, and 526 of FIG. 7 to FIG. 9. The first conductive pattern 130, the second gate electrode 230, and the second conductive pattern 330 may be formed by patterning the first to third conductive films 531, 532, and 533 in FIG. 7 to FIG. 9. The first capping line 136, the second gate capping film 236, and the fourth capping line 336 may be formed by patterning the first capping film 536 of FIG. 7 to FIG. 9.

The second capping line 137, the etch stop layer 237, and the fifth capping line 337 may be formed at the same level. The peripheral interlayer insulating film 245 may be formed on the etch stop layer 237. The third capping line 138, the peripheral circuit capping film 238, and the sixth capping line 338 may be formed at the same level.

The key trench KPt may be defined on the third area III. For example, the key trench KPt may be defined by an inner side surface of the second base insulating pattern 320, an inner side surface of the second conductive pattern 330, and/or an inner side surface of the second capping pattern 335.

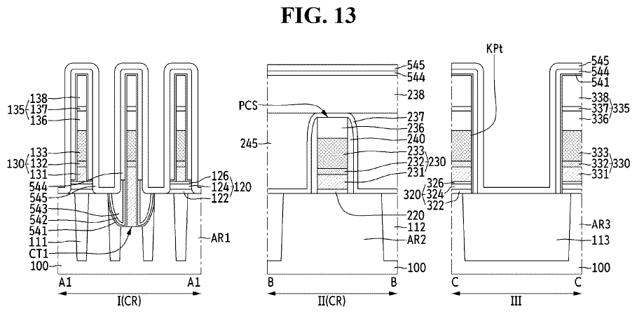

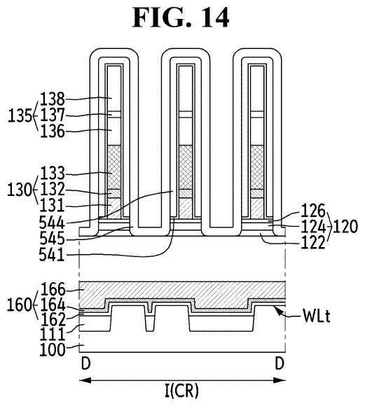

Referring to FIG. 13 and FIG. 14, first to fifth spacer films 541, 542, 543, 544, and 545 are formed.

The first spacer film 541 may be formed on the first area I and the third area III. The first spacer film 541 may extend along the upper surface of the first base insulating pattern 120, the side surface of the first conductive pattern 130, the first capping pattern 135, the upper surface of the second base insulating pattern 320, the side surface of the second conductive pattern 330 and the side surface of the second capping pattern 335.

The second spacer film 542 may be formed on the first area I. The second spacer film 542 may be formed on the first spacer film 541 within the first contact trench CT1. The third spacer film 543 may be formed on the second spacer film 542 within the first contact trench CT1.

The fourth spacer film 544 and the fifth spacer film 545 may be sequentially stacked on the first area I, the second area II, and the third area III.

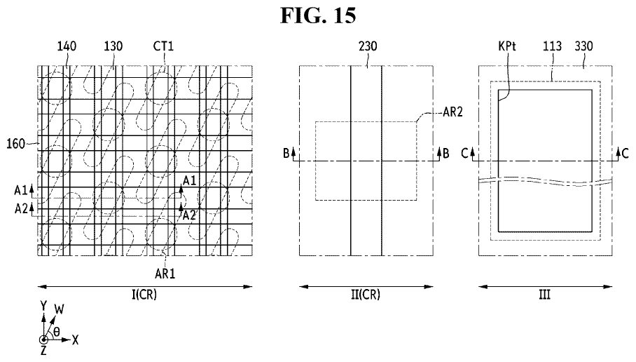

Referring to FIG. 15 to FIG. 17, the second contact trench CT2 is formed within the first area I.

The second contact trench CT2 may expose the second portion (e.g., each of both opposing ends) of the first active pattern AR1. Moreover, in the process of forming the second contact trench CT2, the first spacer structure 140 and the second spacer structure 340 may be formed.

The first spacer structure 140 may be formed by patterning the first to fifth spacer films 541, 542, 543, 544, and 545 on the first area I. Thus, on the first area I, the bit-line structure BLS including the first base insulating pattern 120, the first conductive pattern 130, the first capping pattern 135, and the first spacer structure 140 may be formed.

The second spacer structure 340 may be formed by patterning the first spacer film 541, the fourth spacer film 544, and the fifth spacer film 545 on the second area II. Thus, on the third area III, the alignment key structure AKS including the second base insulating pattern 320, the second conductive pattern 330, the second capping pattern 335, and the second spacer structure 340 may be formed.

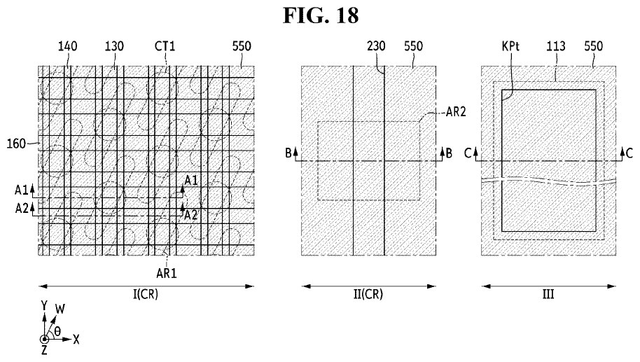

Referring to FIG. 18 to FIG. 20, a contact film 550 is formed.

The contact film 550 may be formed on the first area I, the second area II, and the third area III. The contact film 550 on the first area I may cover or be on the side and upper surfaces of the bit-line structure BLS. Moreover, the contact film 550 on the first area I may fill or be in the second contact trench CT2. The contact film 550 on the second area II may cover or be on the upper surface of the peripheral circuit capping film 238. The contact film 550 on the third area III may cover or be on the side and upper surfaces of the alignment key structure AKS. Moreover, the contact film 550 on the third area III may fill or be in the key trench KPt.

The contact film 550 may include a conductive material such as at least one of polysilicon, TiN, TiSiN, tungsten, tungsten silicide, and combinations thereof. However, embodiments of the present disclosure are not limited thereto. For example, the contact film 550 may include a polysilicon (poly-Si) film. In some embodiments, the contact film 550 may include a film made of a conductive semiconductor material, for example, polysilicon (poly-Si) doped with impurities.

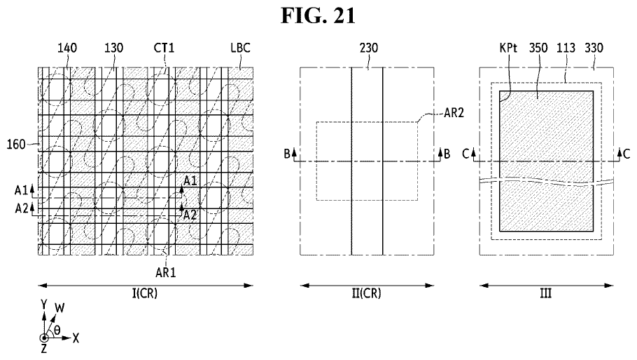

Referring to FIG. 21 to FIG. 23, a line contact LBC and the buried pattern 350 are formed.

For example, a first planarization process may be performed on the contact film 550 in FIG. 18 to FIG. 20. The first planarization process may include, but is not limited to, a chemical mechanical polishing (CMP) process. As the first planarization process is performed, the upper surface of the bit-line structure BLS and the upper surface of the alignment key structure AKS may be exposed. The contact film 550 on the first area I may form the line contact LBC, and the contact film 550 on the third area III may form the buried pattern 350.

The line contact LBC may extend in an elongated manner in the second direction Y while being disposed on the side surface of the bit-line structure BLS. Adjacent ones of the plurality of line contacts LBC extending in a parallel manner to each other and in the second direction Y may be isolated from each other via each of the plurality of bit-line structures BLS extending in a parallel manner to each other and in the second direction Y.

The buried pattern 350 may fill at least a portion of or be in the key trench KPt. In some embodiments, the upper surface of the buried pattern 350 may include the first concave surface 350u having a concave shape. This may be due to a dishing phenomenon that occurs as a width of the key trench KPt is relatively larger than a spacing between the bit-line structures BLS.

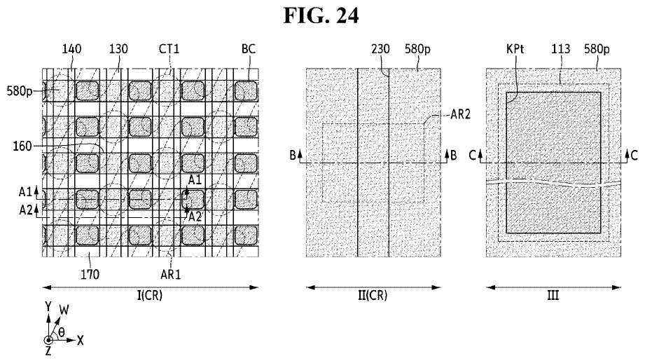

Referring to FIG. 24 to FIG. 26, the buried contact BC and the insulating fence 170 are formed using a mask film 580p.

The mask film 580p may be formed on the first area I, the second area II, and the third area III. The mask film 580p on the first area I may extend along the upper surface of the bit-line structure BLS and the upper surface of the line contact LBC. The mask film 580p on the first area I may form a plurality of line patterns that are spaced apart from each other and extend in a parallel manner to each other and in the first direction X. The mask film 580p on the second area II may extend along the upper surface of the peripheral circuit capping film 238. The mask film 580p on the third area III may extend along the upper surface of the alignment key structure AKS and the upper surface of the buried pattern 350. In some embodiments, when the upper surface of the buried pattern 350 includes the first concave surface 350u, an upper surface of the portion of the mask film 580p on the third area III may include a second concave surface 580u.

The mask film 580p may include an oxide. However, embodiments of the present disclosure are not limited thereto.

An etching process on the line contact LBC may be performed using the mask film 580p as an etch mask. As the line contact LBC is patterned using the mask film 580p on the first area I, the plurality of buried contacts BC that are isolated from each other in the second direction Y may be formed.

Subsequently, the insulating fence 170 may be formed to fill or be in a space obtained by removing the line contact LBC. Adjacent ones of the plurality of buried contacts BC arranged along the second direction Y may be isolated from each other via each of the insulating fences 170 extending in a parallel manner to each other and in the first direction X. For example, the plurality of bit-line structures BLS and the plurality of insulating fences 170 may form a plurality of isolated areas arranged in a lattice structure therebetween. The buried contacts BC may be respectively formed within the isolated areas and thus may be isolated from each other.

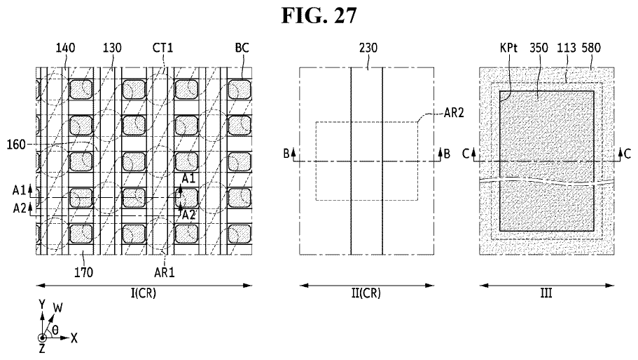

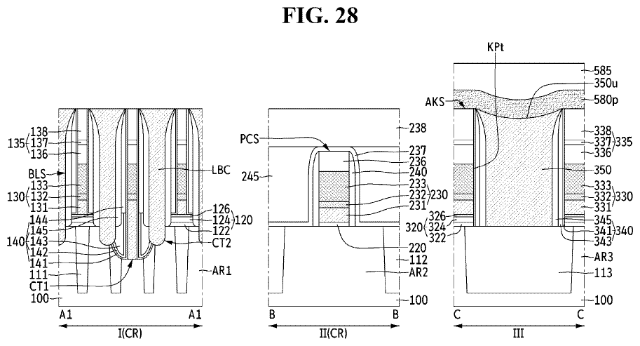

Referring to FIG. 27 and FIG. 28, the mask pattern 580 is formed on the third area III.

The mask pattern 580 may be formed by patterning the mask film 580p of FIG. 24 to FIG. 26. For example, a photoresist film 585 may be formed to cover or be on the mask film 580p on the third area III. The photoresist film 585 may be formed on the third area III and may not be formed on the first area I and the second area II. Subsequently, an etching process may be performed on the mask film 580p using the photoresist film 585 as an etch mask. In this way, the mask pattern 580 exposing the bit-line structure BLS and the buried contact BC on the first area I and exposing the peripheral circuit capping film 238 on the second area II and covering the alignment key structure AKS and the buried pattern 350 the third area III may be formed.

The photoresist film 585 may be removed after the mask pattern 580 has been formed.

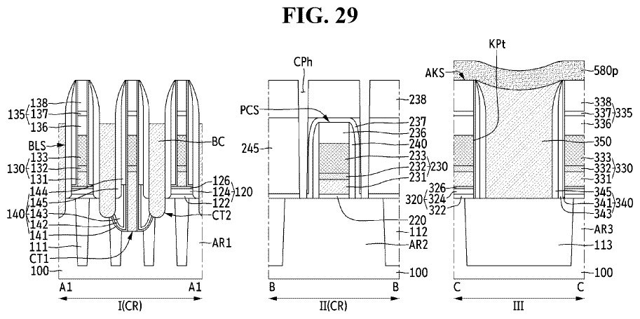

Referring to FIG. 29, an etch-back process is performed on the buried contact BC.

As the etch-back process is performed, an upper portion of the buried contact BC may be removed. For example, after the etch-back process has been performed and relative to the lower (or upper) surface of the substrate 100, a level of the upper surface of the buried contact BC in the fourth direction Z may be lower than a level of the upper surface of the first capping pattern 135 in the fourth direction Z.

During the etch-back process, the buried pattern 350 may not be etched. Specifically, the buried pattern 350 may be protected by the mask pattern 580 during the etch-back process. Accordingly, after the etch-back process has been performed and relative to the lower (or upper) surface of the substrate 100, a level of the upper surface of the buried pattern 350 in the fourth direction Z may be higher than the level of the upper surface of the buried contact BC in the fourth direction Z.

In some embodiments, a plug hole CPh may be formed on the second area II. The plug hole CPh may sequentially extend through the peripheral circuit capping film 238, the peripheral interlayer insulating film 245, and the etch stop layer 237 to expose a portion of the second active pattern AR2. In some embodiments, the forming of the plug hole CPh may be performed after the etch-back process has been performed.

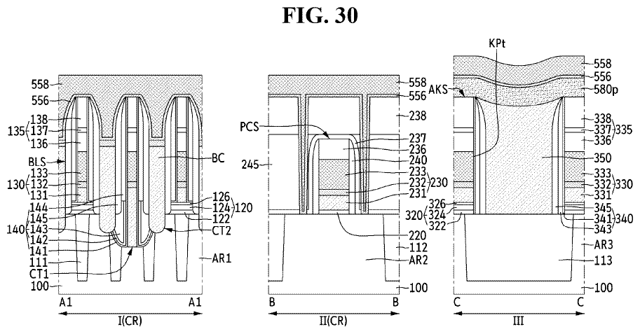

Referring to FIG. 30, a pre-barrier conductive film 556 and a pre-filling metal film 558 are formed.

The pre-barrier conductive film 556 and the pre-filling metal film 558 may be sequentially stacked on the first area I, the second area II, and the third area III. The pre-barrier conductive film 556 and the pre-filling metal film 558 on the first area I may be connected to the upper surface of the buried contact BC, and may cover or be on the side and upper surfaces of the bit-line structure BLS. The pre-barrier conductive film 556 and the pre-filling metal film 558 on the second area II may fill or be in the plug hole CPh in FIG. 29 and may cover or be on the upper surface of the peripheral circuit capping film 238. The pre-barrier conductive film 556 and the pre-filling metal film 558 on the third area III may cover or be on the upper surface of the mask pattern 580.

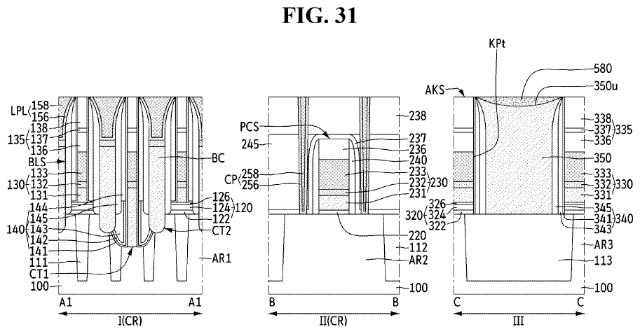

Referring to FIG. 31, the lower pad LPL and the contact plug CP are formed.

For example, a second planarization process may be performed on the pre-barrier conductive film 556 and the pre-filling metal film 558 in FIG. 30. The second planarization process may include, but is not limited to, a chemical mechanical polishing (CMP) process. As the second planarization process is performed, the upper surface of the bit-line structure BLS and the upper surface of the peripheral circuit capping film 238 may be exposed. The pre-barrier conductive film 556 and the pre-filling metal film 558 on the first area I may form the lower pad LPL. The pre-barrier conductive film 556 and the pre-filling metal film 558 on the second area II may form the contact plug CP.

In some embodiments, as shown, after the second planarization process has been performed, the mask pattern 580 may expose the upper surface of the alignment key structure AKS. For example, relative to the lower (or upper) surface of the substrate 100, a level of the upper surface of the mask pattern 580 in the fourth direction Z may be equal to a level of the upper surface of the alignment key structure AKS in the fourth direction Z.

In some embodiments, unlike what is shown, after the second planarization process has been performed, the mask pattern 580 may cover or be on the upper surface of the alignment key structure AKS and the upper surface of the buried pattern 350. For example, relative to the lower (or upper) surface of the substrate 100, a level of the upper surface of the mask pattern 580 in the fourth direction Z may be higher than a level of the upper surface of the alignment key structure AKS in the fourth direction Z.

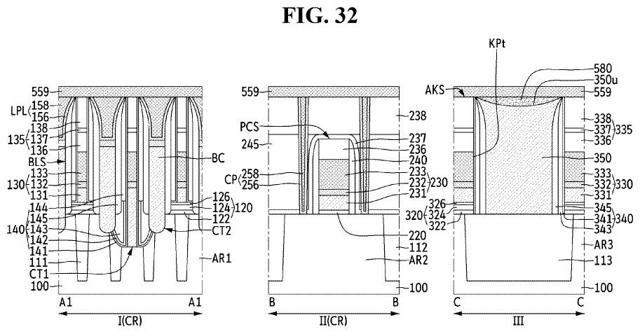

Referring to FIG. 32, an upper conductive film 559 is formed.

The upper conductive film 559 may be formed on the first area I, the second area II, and the third area III. The upper conductive film 559 on the first area I may be connected to the lower pad LPL and may extend along the upper surface of the lower pad LPL and the upper surface of the bit-line structure BLS. The upper conductive film 559 on the second area II may be connected to the contact plug CP and may extend along the upper surface of the contact plug CP and the upper surface of the peripheral circuit capping film 238. The upper conductive film 559 on the third area III may cover or be on the alignment key structure AKS and/or the mask pattern 580.

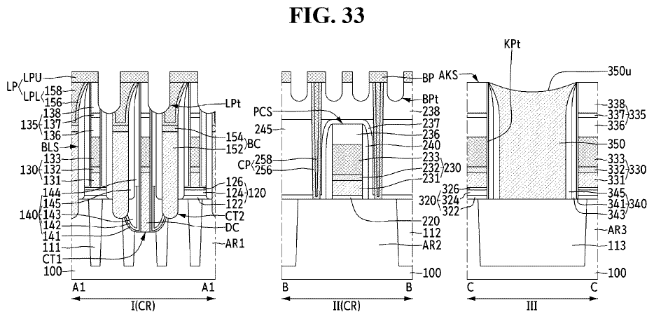

Referring to FIG. 33, the pad trench LPt and the wiring trench BPt are formed.

The pad trench LPt may be formed on the first area I. The pad trench LPt may define the landing pad LP that forms the plurality of isolated areas spaced apart from each other on the first area I.

The wiring trench BPt may be formed on the second area II. The wiring trench BPt may define a plurality of wiring patterns BP that are spaced apart from each other on the second area II.

In some embodiments, the forming of the pad trench LPt and the wiring trench BPt may be performed in an overlay measurement process using the alignment key structure AKS as an alignment key or an overlay key.

In some embodiments, the pad trench LPt and the wiring trench BPt may be formed at the same level.

In some embodiments, as shown, the mask pattern 580 in FIG. 32 may be removed after the pad trench LPt and the wiring trench BPt have been formed.

In some embodiments, unlike what is shown, at least a portion of the mask pattern 580 in FIG. 32 may remain after the pad trench LPt and wiring trench BPt are formed.

As described above, the method for manufacturing the semiconductor device according to some embodiments may protect the alignment key structure AKS and the buried pattern 350 using the mask pattern 580. The mask pattern 580 may prevent or inhibit damage to the alignment key structure AKS during the second planarization process to improve the yield and productivity of the semiconductor device.

Specifically, as the spacing between adjacent landing pads LP is reduced, a connection defect such as mutual interference or connection between adjacent landing pads LP may occur. To prevent the connection defect, the landing pad LP including the lower pad LPL and the upper pad LPU formed separately from the lower pad LPL may be provided. In this regard, if the mask pattern 580 is not provided, the alignment key structure AKS formed at the same level as the bit-line structure BLS may be damaged in the second planarization process to form the lower pad LPL. For example, if the mask pattern 580 is not provided, at least a portion of the buried pattern 350 may be etched in the etch-back process for the buried contact BC. Since the key trench KPt has a relatively larger width, the etched buried pattern 350 may cause damage to the alignment key structure AKS in the second planarization process.

On the contrary, in the method for manufacturing the semiconductor device according to some embodiments, the buried pattern 350 may be protected using the mask pattern 580 in the second planarization process. The protected buried pattern 350 may fill or be in a large portion or an entirety of the key trench KPt to prevent or inhibit the alignment key structure AKS from being damaged in the second planarization process.

Moreover, in the method for manufacturing the semiconductor device according to some embodiments, the mask pattern 580 may be used to prevent or inhibit the silicide film from being formed on the upper surface of the buried pattern 350, thereby preventing or inhibiting contamination due to the silicide film.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

1. A semiconductor device comprising:
a substrate that comprises a first area and a second area;
a first active pattern in the first area;
a bit-line structure on the first area;
a buried contact that is on a side surface of the bit-line structure and is electrically connected to the first active pattern of the first area;
an alignment key structure that is on the second area and defines a key trench; and
a buried pattern in at least a portion of the key trench,
wherein the buried contact and the buried pattern comprise a first conductive material, and
wherein, relative to an upper surface of the substrate and in a direction that is perpendicular to the upper surface of the substrate, a height of an upper surface of the buried pattern is greater than a height of an upper surface of the buried contact.

2. The semiconductor device of claim 1, wherein:
the bit-line structure comprises a first conductive pattern and a first capping pattern on the first conductive pattern,
the alignment key structure comprises a second conductive pattern and a second capping pattern on the second conductive pattern,
the first conductive pattern and the second conductive pattern comprise a second conductive material, and
the first capping pattern and the second capping pattern comprise a same insulating material.

3. The semiconductor device of claim 1, wherein a thickness of the bit-line structure in the direction and a thickness of the alignment key structure in the direction are equal to each other.

4. The semiconductor device of claim 1, wherein the upper surface of the buried pattern has a concave shape.

5. The semiconductor device of claim 1, wherein the upper surface of the buried pattern is directly connected to an upper surface of the alignment key structure.

6. The semiconductor device of claim 1, wherein, relative to the upper surface of the substrate, the height of an uppermost surface of the buried pattern in the direction is equal to a height of an upper surface of the alignment key structure in the direction.

7. The semiconductor device of claim 1, wherein each of the buried contact and the buried pattern comprises a polysilicon film.

8. The semiconductor device of claim 1, further comprising a mask pattern on the upper surface of the buried pattern, wherein the mask pattern does not overlap the first area in the direction.

9. The semiconductor device of claim 1, further comprising an element isolation pattern that is in the second area and defines a second active pattern of the second area, wherein the buried pattern is on an upper surface of the element isolation pattern.

10. The semiconductor device of claim 1, further comprising a capacitor structure electrically connected to the buried contact.

11. A semiconductor device comprising:
a substrate that comprises a chip area and a scribe lane area at least partially surrounding the chip area in plan view;
a first active pattern in the chip area;
a bit-line structure that is on the chip area, extends in a first direction, and is electrically connected to a first portion of the first active pattern;
a buried contact that is on a side surface of the bit-line structure and is electrically connected to a second portion of the first active pattern;
a gate electrode that extends in a second direction intersecting the first direction and extends between the first portion of the first active pattern and the second portion of the first active pattern;
a capacitor structure that is on the bit-line structure and the buried contact and is electrically connected to the buried contact;
an alignment key structure that is on the scribe lane area and comprises a key trench; and
a buried pattern in at least a portion of the key trench,
wherein the bit-line structure and the alignment key structure comprise a first conductive material,
wherein the buried contact and the buried pattern comprise a second conductive material,
wherein, relative to an upper surface of the substrate and in a third direction that is perpendicular to the first direction and the second direction, a height of an upper surface of the buried pattern is greater than a height of an upper surface of the buried contact.

12. The semiconductor device of claim 11, wherein:
the bit-line structure comprises a first conductive pattern and a first capping pattern on the first conductive pattern,
the alignment key structure comprises a second conductive pattern and a second capping pattern on the second conductive pattern,
the first conductive pattern and the second conductive pattern comprise a third conductive material,
the first capping pattern and the second capping pattern comprise a first insulating material.

13. The semiconductor device of claim 12, wherein:
the bit-line structure further comprises a first spacer on a side surface of the first conductive pattern and a side surface of the first capping pattern,
the alignment key structure further comprises a second spacer on a side surface of the second conductive pattern and on a side surface of the second capping pattern,
the first spacer and the second spacer each comprise a second insulating material.

14. The semiconductor device of claim 12, wherein, relative to the upper surface of the substrate, a height of an upper surface of the first conductive pattern in the third direction and a height of an upper surface of the second conductive pattern in the third direction are equal to each other.

15. The semiconductor device of claim 11, wherein the upper surface of the buried pattern has a concave shape.

16. The semiconductor device of claim 11, wherein relative to the upper surface of the substrate, the height of the upper surface of the buried pattern in the third direction is equal to a height of an upper surface of the alignment key structure in the third direction.

17. The semiconductor device of claim 11, wherein each of the buried contact and the buried pattern comprises a polysilicon film.

18. A semiconductor device comprising:
a substrate that comprises a chip area and a scribe area;
a first active pattern in the chip area;
a bit-line structure on the chip area;
a buried contact that is on a side surface of the bit-line structure and is electrically connected to the first active pattern of the chip area;
an alignment key structure that is on the scribe area and defines a key trench; and
a buried pattern in at least a portion of the key trench,
wherein, relative to an upper surface of the substrate and in a direction that is perpendicular to the upper surface of the substrate, a height of an upper surface of the buried pattern is greater than a height of an upper surface of the buried contact in the direction, and
wherein the buried pattern is free of a silicide film.

19. The semiconductor device of claim 18, further comprising a mask pattern that at least partially overlaps the buried pattern in the direction.

20. The semiconductor device of claim 1, wherein:
the bit-line structure comprises a first conductive pattern and a first capping pattern on the first conductive pattern,
the alignment key structure comprises a second conductive pattern and a second capping pattern on the second conductive pattern,
the first conductive pattern and the second conductive pattern each comprise a same conductive material, and
the first capping pattern and the second capping pattern each comprise a same insulating material.

21-23. (canceled)
